(19) United States
(12) Patent Application Publication
(10) Pub. No.: US 2026/0185205 A1
(43) Pub. Date: Jul. 2, 2026

(54) TEMPLATE FOR METAL ELECTRODE PATTERNING, STRETCHABLE METAL ELECTRODE USING THE SAME AND MANUFACTURING METHOD THEREOF

(71) Applicant: SEOUL NATIONAL UNIVERSITY R&DB FOUNDATION, Seoul (KR)

(72) Inventors: Yong Taek HONG, Seoul (KR); Hyung Soo YOON, Seoul (KR); Su Jin JEONG, Seoul (KR)

(73) Assignee: SEOUL NATIONAL UNIVERSITY R&DB FOUNDATION, Seoul (KR)

(21) Appl. No.: 18/841,067

(22) PCT Filed: Jul. 1, 2024
(86) PCT No.: PCT/KR2024/009193

§ 371 Date: Aug. 23, 2024

(30) Foreign Application Priority Data
Jul. 31, 2023 (KR) 10-2023-0099666

(51) Int. Cl. C23C 14/04; C23C 14/20; H10H 20/01; H10H 20/857

(52) U.S. Cl. CPC C23C 14/04; C23C 14/20; H10H 20/0364; H10H 20/857

(57) ABSTRACT

The present invention relates to a template for metal electrode patterning capable of patterning a metal electrode selectively without a mask, which comprises a first region in which a material that interferes with metal deposition is printed on the surface and a second region forming a location where the metal is to be deposited.

### TECHNICAL FIELD

The present invention relates to a means for depositing a metal on a substrate and a substrate deposited using the same and a method for deposition thereof.

### BACKGROUND ART

A method for forming a conductive metal pattern using vacuum deposition is a technology widely used in various fields such as metal wiring for electrical and electronic circuits or electrodes of OLED light emitting devices for displays and semiconductor devices and the like. The most common method forming a conductive metal pattern using vacuum deposition is a method using a metal mask, and generally, it is a method of physically removing a metal from the region where a pattern is to be formed by processing an alloy having a low thermal expansion coefficient, thereby preparing a metal mask, and selectively depositing an electrode through the removed portion of this mask.

Conventional electronic circuits and devices have morphological limitations that they had to be made on a plane. However, with the recent development of flexible and stretchable materials, attempts to implement tensionable electronic circuits and devices and to implement devices on stretchable substrates have been made.

Metals, materials mainly used as an electrode, are representative conductive materials showing high conductivity and optical properties that can be adjusted from translucency to reflection. Even sufficiently metal thin films can be used as flexible electrodes, as they have some mechanical durability, but a problem that cracks can occur at a strain of about 2% and lead to electrical defects is known. Tensile strain is essential to form a stretchable electrode, so self-stretchability of the electrode is required, but as described above, there are difficulties in application, since the metal electrode is vulnerable to tension.

In addition, for metal electrode patterning, a rigid shadow mask or photo mask should be used, but there is a limitation that the process complexity increases, sine a subsequent process to remove the mask after a deposition process and leave only the required metal thin film.

### DISCLOSURE

### Technical Problem

The present invention is to solve the problems of the prior art described above, and an object is to provide a template for metal electrode patterning that can pattern a metal electrode on an elastic substrate without a shadow mask or photo mask in the deposition process and a stretchable electrode prepared using the same and a manufacturing method thereof.

### Technical Solution

The template for metal electrode patterning suggested in one example of the present invention comprises an elastic substrate, and comprises a first region in which a material that interferes with metal deposition is printed on the surface and a second region that forms a location where a metal is deposited.

According to one example, the substrate may comprise at least one of polymers consisting of Styrene-Ethylene/Butylene-Styrene (SEBS) and polydimethylsiloxane (PDMS), and comprise a network structure formed by the polymers inside.

According to one example, the material that interferes with metal deposition may comprise at least one selected from the group consisting of Poly(vinylidene fluoride-co-hexafluoropropylene) (PVDF-HFP), trichloro(1H,1H,2H,2H-perfluorooctyl)silane (FOTS), poly(3,3,4,4,5,5,6,6,7,7,8,8,8-tridecafluorooctylmethacrylate (PFOMA) and (poly(1H,1H,2H,2H-perfluorodecyl methacrylate) (PFDMA).

According to one example, the substrate may have a Normalized Resistance (R/R0) value of 70 or less within a uniaxial tensile strain of 0% to 100%.

According to one example, the material that interferes with metal deposition may be made of a material exhibiting a tensile stress of less than 0.4 MPa within a tensile strain of 0% to 800%.

According to another example, a patterned metal electrode formed on a substrate may comprise a first region in which a material that interferes with metal deposition is printed on the surface and a second region in which a metal electrode is deposited on the surface, and comprise an elastic substrate comprising a polymer network structure inside, and have an intermediate layer formed, in which metal atoms are impregnated into the network structure formed by polymers inside the substrate in the thickness direction from the surface where the electrode of the second region is formed.

According to one example, the metal electrode may be formed of at least one metal selected from the group consisting of gold (Au), silver (Ag), magnesium (Mg), copper (Cu), iron (Fe) and calcium (Ca) or alloy thereof.

According to one example, the metal electrode may comprise a pattern formed by physical vapor deposition (PVD).

According to one example, the metal electrode may have a pattern formed without a mask only in the second region other than the first region in which a material that interferes with metal deposition is printed.

According to one example, in the intermediate layer, some metal atoms of the electrode may be impregnated into the network structure formed by polymers inside the substrate at a ratio of 30 to 90%.

According to another example, a light emitting device combined to a patterned metal electrode formed on a template may comprise a first region in which a material that interferes with metal deposition is printed on the surface and a second region in which a metal electrode is deposited on the surface, and comprise an elastic substrate comprising a network structure formed by polymers inside, and have an intermediate layer formed, in which metal atoms are impregnated into the network structure formed by polymers inside the substrate in the thickness direction from the surface where the electrode of the second region is formed, and the metal electrode may be electrically connected to the light emitting device.

According to one example, the elastic substrate may be capable of being strained within a tensile strain range of 0 to 200%.

According to another example, a manufacturing method of a patterned metal electrode formed on a template may be a manufacturing method of a metal electrode, comprising preparing an preparing an elastic substrate, comprising forming a first region by printing a material that interferes with metal deposition on the substrate, comprising heat-treating the printed substrate, and comprising forming a metal electrode by exposing the heat-treated substrate to metal vapor in a high vacuum chamber, and it may be performed using the template for metal electrode patterning.

### Advantageous Effects

According to the composition of the present invention, a metal electrode capable of being strained on a substrate without electrical defects using a template that can pattern a metal electrode without a mask in a simple process can be formed.

The template can be composed of heterogeneous elastomers, and it has advantages that it can, not only pattern a stretchable metal electrode using unique impregnation and desorption reaction shown by each elastomer when a metal is deposited, but also secure a conductive path of a patterned electrode using micro-crack formation due to tension.

The metal electrode formed on the template for metal electrode patterning of the present invention is a stretchable electrode that maintains electrical properties despite mechanical deformation, and further, it can be universally used in various soft electronics fields such as a wearable device for health monitoring, a stretchable device, a human-machine interface, a freeform display, a tactile sensor and the like.

### BRIEF DESCRIPTION OF THE DRAWINGS

FIG. 1, is a schematic diagram which schematically shows the structure of the template for metal electrode patterning according to one example of the present invention.

FIG. 2, is a form of the elastic substrate in which a metal electrode is patterned on the template for metal electrode patterning according to one example of the present invention.

FIG. 3, is photographs which observe the surface of the elastic substrate in which gold (Au) or silver (Ag) is patterned with a metal electrode on the template for metal electrode patterning according to one example of the present invention.

FIG. 4, is a graph of electrode resistance changes according to tensile strain in a range of 0 to 100% in the uniaxial direction applied to a metal electrode in which gold (Au) or silver (Ag) is patterned on the template for metal electrode patterning according to one example of the present invention with a thickness of 50 nm.

FIG. 5, is graphs of resistance changes of the silver (Ag) electrode when applied repeatedly 100 times in a tensile strain range of 0 to 30% to a silver (Ag) electrode patterned on the template for metal electrode patterning according to one example of the present invention.

FIG. 6, is a graph of resistance changes of the gold (Au) electrode when applied repeatedly 100 times in a tensile strain range of 0 to 50% to a gold (Au) electrode patterned on the template for metal electrode patterning according to one example of the present invention.

FIG. 7, is a graph of voltage changes in a tensile strain range of 0 to 50%, which is one in which a micro-LED, a light emitting device is combined on the metal electrode patterned on the template for metal electrode patterning according to one example of the present invention.

FIG. 8 is a flowchart of the manufacturing method of the patterned metal electrode formed on the template for metal electrode patterning according to one example of the present invention.

### MODE FOR INVENTION

Examples of the present disclosure are illustrated for the purpose of describing the technical spirit of the present disclosure. The scope according to the present disclosure are not limited to examples presented below or specific description of these examples.

All technical terms and scientific terms used in the present disclosure have meanings commonly understood by those skilled in the art to which the present disclosure belongs, unless otherwise defined. All terms used in the present disclosure are selected for the purpose of more clearly describing the present disclosure, and are not selected to limit the scope according to the present invention.

Expressions such as “comprising”, “providing”, “having” and the like used in the present disclosure, should be understood in open-ended terms encompassing the possibility of including other examples, unless otherwise stated in a phrase or sentence in which the corresponding expression is included.

In the present invention, when a part such as a layer, membrane, area, plate and the like is said to be “above” or “on” another part, this includes not only the case in that it is “directly on” another part, but also the case in that there is another part in between. On the contrary, when a part is said to be “right above” another part, it means that there is no other part in between. In addition, that it is said to be “above” or “on” the standard part means being positioned above or below of the standard part, and does not necessarily mean being positioned “above” or “on” the direction opposite to gravity.

In the present invention, “plane image” refers to the object of the present invention viewed from above, and “cross-sectional image” means the cross section, in which the object of the present invention is vertically cut, viewed from the side.

Expressions in a singular form described in the present disclosure may include a meaning of a plural form unless otherwise stated, and this is equally applied to expressions in a singular form described in claims.

Hereinafter, with reference to the accompanied drawings, the examples of the present invention will be described. In this process, the thickness of the lines or sizes of the elements, and the like illustrated in the drawings may be exaggeratedly illustrated for clarity and convenience of description. In addition, in the description of the following examples, describing the same or corresponding elements repeatedly may be omitted. However, even if description of the elements is omitted, it is not intended that such elements are not included in any example.

In addition, the following examples does not limit the scope of the present invention, but are only illustrative of elements presented in the claims of the present invention, and examples which are included in the technical spirit throughout the description of the present invention and can be replaced as equivalents in the elements of the claims may be included in the scope of the present invention.

The present invention relates to a template for metal electrode patterning comprising a first region in which a material that interferes with metal deposition on an elastic substrate is printed and a second region which forms a location where the metal is deposited, and more specifically, relates to a template capable of patterning a metal electrode on an elastic substrate without a commonly used shadow mask or photo mask, and an electrode prepared thereby and a manufacturing method thereof.

The present invention relates to a template capable of selectively patterning a metal electrode on an elastic substrate without a shadow mask or photo mask, and provides a template for metal electrode patterning comprising an elastic substrate.

The template for metal electrode patterning comprises an elastic substrate, and may comprise a first region in which a material that interferes with metal deposition on an elastic substrate is printed; and a second region which forms a location where the metal is deposited.

The substrate may be formed to comprise a different kind of elastomer, and through this, it has an advantage that microcracks may be generated on the surface of the substrate, but the metal electrode is not damaged or the substrate is not significantly damaged, even if a significant load of tensile strain is applied in a state that a patterned metal is deposited.

The elastic substrate may comprise at least one of polymers consisting of Styrene-Ethylene/Butylene-Styrene (SEBS) and polydimethylsiloxane (PDMS), and preferably, Styrene-Ethylene/Butylene-Styrene (SEBS) substrate may be used.

The inside of the substrate may comprise a network structure formed by the polymers. The network structure is a complex matrix formed by irregularly intertwining each high-molecular-weight polymer, and may prevent the substrate from being damaged by wear or external impact, and let it have elasticity and moldability.

The elastic substrate may be strained within a tensile strain range of 0 to 200%.

The surface of the substrate may have a bulk-surface, through the polymer network structure. Since the network structure formed by the polymers has an effect of expanding the surface area by forming an irregular surface, it may form a more effectively close contact form than when another material is printed or deposited on the upper part of the substrate.

According to one example, the substrate may have a Normalized Resistance (R/R0) value of 70 or less within a uniaxial tensile strain of 0% to 100%.

The material that interferes with metal deposition may comprise a fluorine functional group and comprise a polymer material with low surface energy. As one example, the material that interferes with the metal may comprise at least one selected from the group consisting of Poly(vinylidene fluoride-co-hexafluoropropylene) (PVDF-HFP), trichloro(1H,1H,2H,2H-perfluorooctyl)silane (FOTS), poly(3,3,4,4,5,5,6,6,7,7,8,8,8-tridecafluorooctylmethacrylate (PFOMA) and (poly(1H,1H,2H,2H-perfluorodecyl methacrylate) (PFDMA), and preferably, it may comprise PVDF-HFP (Poly(vinylidene fluoride-co-hexafluoropropylene)). The printing method of the material that interferes with metal deposition is not particularly limited, but it is preferable to apply it using a solution process, and for this, it may be prepared in a transparent ink form. The material that interferes with the deposition may be preferably a material having not only a property to interfere with deposition, but also stretchability.

The material that interferes with metal deposition should have intrinsically high stretchability, and specifically, it is preferably a material capable of maintaining a film form without breaking even in a tensile strain range of 800%. More preferably, it may maintain a film form without breaking even in a tensile strain range of 1000%. In addition, the material that interferes with metal deposition may be preferably composed of a material exhibiting a tensile stress of less than 0.4 MPa in a tensile strain range of 0% to 800%.

The material that interferes with metal deposition may comprise various solvents such as N-methyl-2-pyrrolidone (NMP), Triethyl phosphate (TEP), Dimethyl sulfoxide (DMSO), Methyl isobutyl ketone (MIBK), Propylene glycol methyl ether acetate (PGMEA), and the like, in order to have physical properties (for example, viscosity, surface tension, boiling point, etc.) suitable for printing equipment.

Furthermore, the material that interferes with metal deposition may further comprise a crosslinking agent to secure mechanical flexibility of a printed pattern. The crosslinking agent may comprise one selected from the group consisting of TAIC (1,3,5-Triallyl-1,3,5-triazinane-2,4,6-trione, BPO (dibenzoyl peroxide), DCP (Dicumyl peroxide), PBP (Perbutyl peroxide), MIKP (Methyl isobutyl ketone peroxide), Dimethyl Di-t-butylperoxy hexane or a mixture thereof.

As one example, the composition ratio of the material that interferes with metal deposition may consist of e-PVDF-HFP of 1 to 50 wt %, a crosslinking agent of 0.05 to 3 wt %, and the remainder solvent.

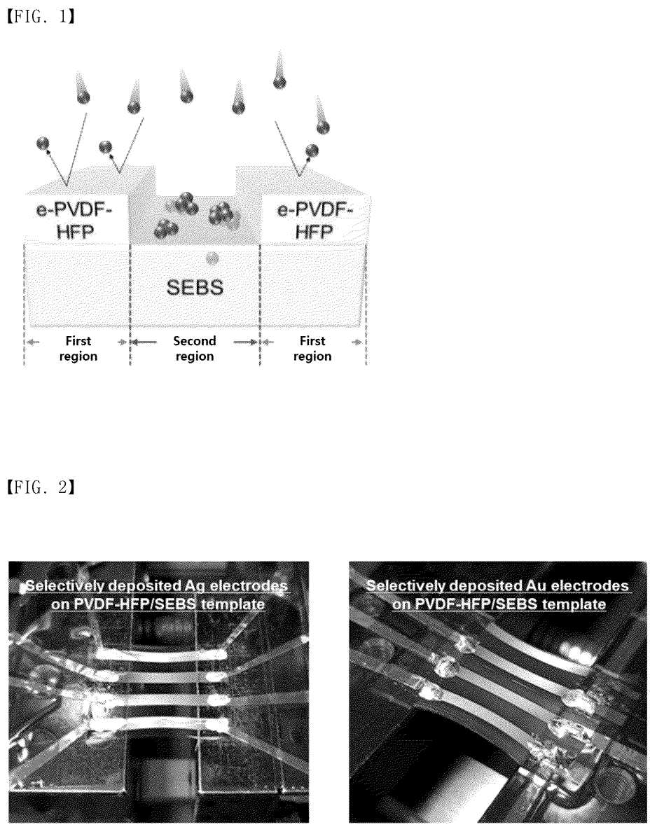

FIG. 1, is a schematic diagram which schematically shows the structure of the template for metal electrode patterning according to one example of the present invention, and illustrates a first region in which a material that interferes with metal deposition is printed on an elastic substrate; and a second region which forms a location where a metal is to be deposited.

The first region may be formed by printing a material that interferes with metal deposition in an engraved pattern on an elastic substrate. The thickness of the printed film is at a level inside and outside of several tens nm to 10 μm, and the applied ink may be used after heat treatment at a room temperature to 180° C., preferably, 100° C. to 150° C. The line width of the pattern to be printed is limited by the ink application method of each process equipment, and for example, when an EHD printer is used, it is possible to implement a pattern with a minimum line width at a level of several tens of μm, so even a fine pattern can be printed.

The material that interferes with metal deposition may be applied using various printing equipment (for example, inkjet printer, pneumatic dispenser, EHD printer), and may be printed to form a certain pattern in an ink form using a printing process. As one example, the material that interferes with metal deposition may be applied using a roll-to-roll coating method.

As described above, the surface of the elastic substrate has an irregular surface by a polymer network structure, so the material that interferes with metal deposition printed in the first region may form a completely close form to the surface of the elastic substrate. The stretchable material that interferes with metal deposition can maintain the completely close form on the elastic substrate without peeling, even if a tension strain is applied, and thus, it can be used as a template for metal electrode patterning.

The second region forms a location where the metal is deposited. The region excluding the first region on the template comprising the elastic substrate may be defined as the second region that forms a location where the metal is deposited. The second region is a region in which the material that interferes with metal deposition is not printed, and the surface of the elastic substrate may be exposed.

Hereinafter, as another example of the present invention, a patterned metal electrode formed on the template using a template for metal electrode patterning will be described in detail. The metal electrode formed by such a method may be applied as an electrode or a substrate in which an electrode is equipped of various devices.

According to one example, the patterned metal electrode formed on the template may comprise a first region in which a material that interferes with metal deposition is printed on the surface and a second region in which a metal electrode is deposited on the surface, and comprise an elastic substrate comprising a polymer network structure inside, and have an intermediate layer in which metal atoms are impregnated into the network structure formed by polymers inside the substrate in the thickness direction from the surface where the electrode of the second region is formed.

The metal electrode may be formed by exposing metal vapor is exposed on a template for metal electrode patterning in a high-vacuum state. Deposition of the metal electrode may be performed by transferring the template for metal electrode patterning into a vacuum deposition chamber under high vacuum, preferably, under pressure below 10⁻⁶ Torr. As one example, the metal electrode may comprise a pattern formed by Physical Vapor Deposition (PVD).

According to one example, the metal electrode may be formed of at least one metal selected from the group consisting of gold (Au), silver (Ag), magnesium (Mg), copper (Cu), iron (Fe) and calcium (Ca) or alloy thereof.

The growth of a deposition thin film of a metal electrode is affected by the surface energy of a substrate, and when the cohesion between metal atoms to be deposited is stronger than interaction with the lower substrate, it follows the Volmer-Weber mode in which the film grows in an island form. In addition, a phenomenon that some sources cannot cause a condensation reaction on the surface on which a material that interferes with metal deposition is applied and are desorbed occurs complexly, thereby controlling the growth rate of the deposition thin film.

When deposition of a metal electrode is performed on a template for metal electrode patterning, in the first region in which a material that interferes with metal deposition is printed, the deposition rate is inhibited, and therefore, a metal thin film is not formed, and only in the second region that forms a location where the metal is deposited, a metal electrode is selectively deposited, so the second region in which the metal electrode is deposited on the surface may be formed. Therefore, even without using a separate mask, selective patterning of a metal electrode is possible without applying an additional wet process.

The second region in which the metal electrode is deposited on the surface is that metal vapor is deposited on the surface of the exposed elastic substrate, and the metal electrode may form a close form to the irregular surface of the elastic substrate. From the metal electrode formed on the surface of the second region, some metal atoms may be diffused into the inside the substrate. The diffused some metal atoms may form an intermediate layer in which some metal atoms are impregnated in the network structure formed by polymers inside the substrate.

The intermediate layer may be formed on the surface of the substrate in the thickness direction, and the depth of the intermediate layer may vary according to deposition conditions such as the type of the deposited metal, deposition rate, deposition thickness and the like. Since some metal vapor is diffused into the network structure of the substrate more deeply when the deposition rate of the metal is low, the thickness of the intermediate layer may be deepened.

As the intermediate layer becomes deeper in the thickness direction from the surface of the substrate, the ratio of the impregnated metal atoms may tend to decrease. The intermediate layer may be one in which some metal atoms of the electrode may be impregnated in the network structure formed by the polymers inside the substrate, preferably, at a ratio of 30 to 90%. The impregnation ratio of the intermediate layer may vary according to deposition conditions such as the type of the metal, deposition rate, deposition thickness, and the like. The impregnation ratio may allow metal atoms to diffuse and penetrate to a deeper depth as deposition is performed at a low deposition rate, and more preferably, when an appropriate thickness of the substrate is formed, the metal atoms may be impregnated at a ratio of 40 to 80%.

Some metal atoms of the intermediate layer may form an interlocking structure by being impregnated into high-molecular-weight polymers which form a network structure. Such a structure may form fine microcracks in the intermediate layer, when mechanical deformation such as tensile strain and the like is applied on an elastic substrate in which a metal electrode is deposited on the surface. As a result, even when a tensile strain is applied, a conductive path is maintained through the microcracks of the intermediate layer, so it is possible to implement a stretchable electrode capable of being strained and a soft electrode having an overall low modulus.

### Example 1

Hereinafter, that the metal electrode formed on the template according to one example of the present invention implements properties of a stretchable electrode will be described in detail by experimental results.

According to the afore-mentioned first embodiment, a gold (Au) or silver (Ag) electrode was formed on the second region of the template, by depositing gold (Au) or silver (Ag) vapor on a template comprising a Styrene-Ethylene/Butylene-Styrene (SEBS) substrate.

FIG. 2 is an image photographed during a tensile test, and it can be confirmed that an elastic substrate in which a gold (Au) or silver (Ag) electrode is patterned on a template is well formed, and can be sufficiently strained. In FIG. 2, it is confirmed that patterning a golf (Au, left image) or silver (Ag, right image) electrode on an elastic substrate is possible, and it can be strained with a patterned metal electrode formed on a template even in a state in which a material that interferes with metal deposition formed on the substrate is not removed.

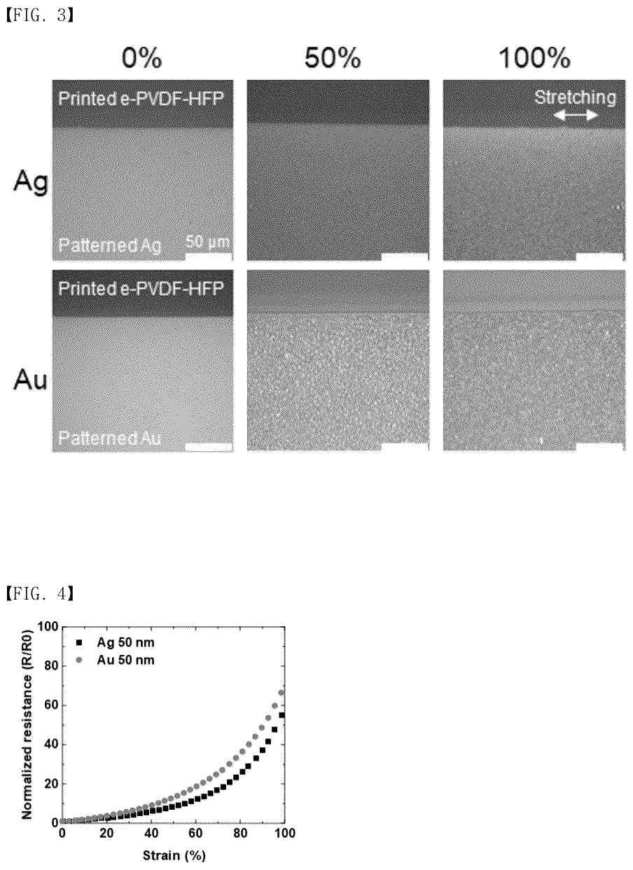

FIG. 3 is a photograph of observing the patterned gold (Au) or silver (Ag) electrode surface on the template with an optical microscope.

In the experiment, the patterned metal electrode formed on the template is photographed using Olympus, DSX510 device, and the metal electrode sample patterned on the PVDF-HFP/SEBS template is fixed to a uniaxial tensile jig and is given tensile strain and is observed with a microscope. The image of FIG. 3 is also photographed in a state in which the material that interferes with metal deposition is not removed, and the transparent region marked “Printed e-PVDF-HFP” is a region in which the material that interferes with metal deposition is formed.

Referring to FIG. 3, it can be confirmed that a gold (Au) or silver (Ag) electrode is not deposited on the surface of the first region in which the material that interferes with metal deposition is printed in the template, and thus, the transmission factor is high when it is observed with a microscope. On the surface of the second region in which the gold (Au) or silver (Ag) electrode is formed, it can be confirmed that a metal electrode is deposited on the surface, and it can be confirmed that micro-cracks are formed in the metal electrode region even in a tensile strain range of 50 to 100%. It can be observed that the material that interferes with metal deposition is close to the lower substrate, and it is deformed in compliance with the movement of the lower substrate without peeling even in a tensile strain range of 50 to 100%. It is understood to be because it is deformed without affecting surrounding stress distribution due to properties of a material with low tensile stress. In addition, the material that interferes with metal deposition does not interfere with formation of microcracks in the metal electrode region, so it can form a structure advantageous for implementing a stretchable electrode.

Referring to FIG. 4, when a tensile strain in a range of tension 0 to 100% of a uniaxial direction is applied to the metal electrode in which gold (Au) or silver (Ag) is patterned in a thickness of 50 nm on the template, and the Normalized Resistance (R/R0) value is 70 or less. It can be confirmed that a conductive path is maintained without disconnection even in a tensile strain of 100%, although resistance increases with tension as microcracks are formed.

Referring to FIG. 5, the Normalized Resistance of the silver (Ag) electrode is not significantly changed, even when a tensile strain in a range of 0 to 30% is applied in to the silver (Ag) electrode patterned on the template repeatedly 100 times.

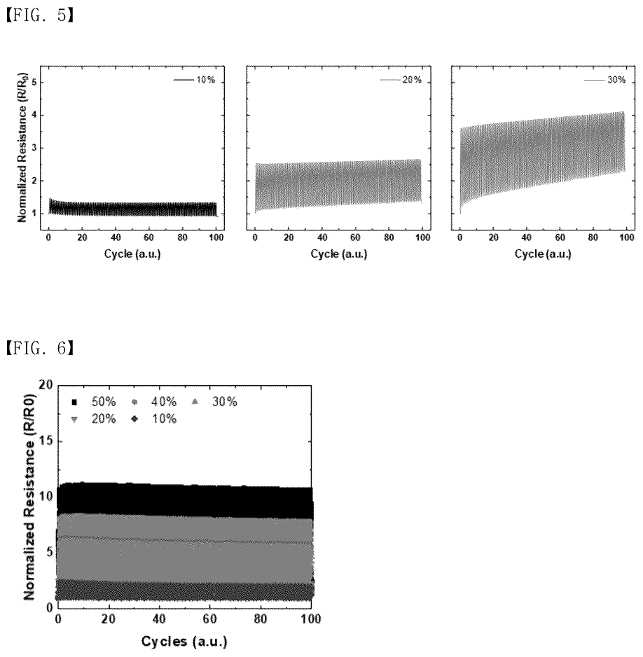

Referring to FIG. 6, the Normalized Resistance of the gold (Au) electrode is maintained, even when a tensile strain in a range of 0 to 50% is applied in to the gold (Au) electrode patterned on the template repeatedly 100 times.

### Example 2

According to one example, a light emitting device combined to a patterned metal electrode formed on a template, may comprise a first region in which a material that interferes with metal deposition is printed on the surface, and comprise a second region in which a metal electrode is deposited on the surface, and comprise an elastic substrate comprising a network structure formed by polymers inside, and an intermediate layer in which metal atoms are impregnated into the polymer network structure inside the substrate may be formed in the thickness direction from the surface where the electrode of the second region is formed, and the metal electrode may be electrically connected to a light emitting device.

In the present invention, the light emitting device is not particularly limited, and any light emitting device electrically connected to an electrode may be used for the present invention. As one example, the light emitting device may be formed by any one selected from the light emitting device group consisting of LED, mini LED and micro LED.

According to one example, the elastic substrate in which the light emitting device is electrically connected may be strained in a tensile strain range of 0 to 200%.

As one example, referring to FIG. 7, in the micro LED electrically connected to the gold (Au) electrode patterned on the template, voltage is not changed even if a tensile strain in a range of 0 to 50% is applied, and even with a tensile strain of 50%, it emits light without electrical defects.

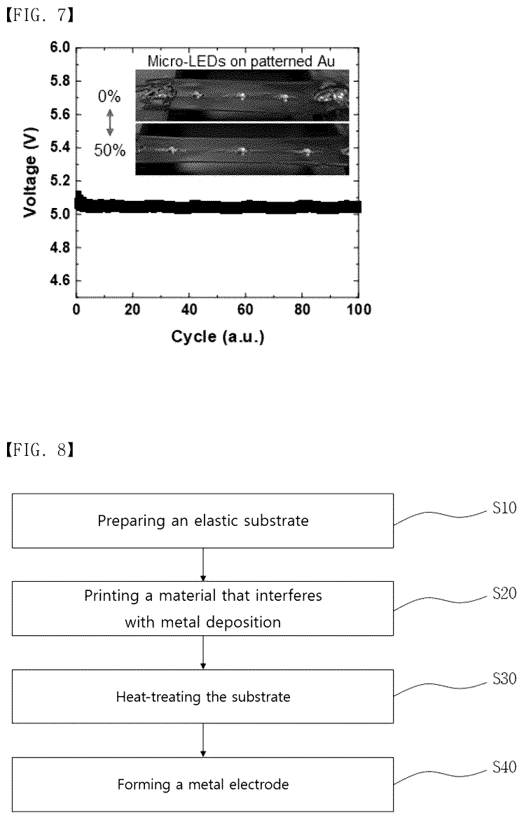

FIG. 8 is a flowchart that shows the manufacturing method of the patterned metal electrode formed on the template. The patterned metal electrode formed on the template uses the afore-mentioned template for metal electrode patterning, and it may comprise preparing an elastic substrate (S10); forming a first region by printing a material that interferes with metal deposition on the substrate (S20); heat-treating the printed substrate (S30); and forming a metal electrode by exposing the heat-treated substrate to metal vapor in a high-vacuum chamber (S40). In each step, description of the configuration of the afore-mentioned template and the repeated configuration will be omitted.

The above description of the present invention is merely intended to illustratively describe the technical spirit of the present invention, and various changes and modifications can be made by those skilled in the art without departing from the essential features of the present invention. Therefore, the examples disclosed herein are not intended to limit the technical spirit of the present invention, but are intended to describe the present invention, and the scope of the technical spirit of the present invention is not limited by these examples. The protection scope of the present invention should be construed by the following claims, and all technical spirits within the equivalent scope thereto should be interpreted as being included in the scope of the present invention.

1. A template for metal electrode patterning,
which is a template comprising an elastic substrate,
wherein the elastic substrate comprises a first region in which a material that interferes with metal deposition is printed on the surface; and
a second region forming a location in which the metal is to be deposited.

2. The template for metal electrode patterning according to claim 1,
wherein the substrate comprises at least one of polymers consisting of Styrene-Ethylene/Butylene-Styrene (SEBS) and polydimethylsiloxane (PDMS), and
the substrate comprises a network structure formed by the polymers inside.

3. The template for metal electrode patterning according to claim 1,
wherein the material that interferes with metal deposition comprises at least one selected from the group consisting of poly(vinylidene fluoride-co-hexafluoropropylene) (PVDF-HFP), trichloro(1H,1H,2H,2H-perfluorooctyl)silane (FOTS), poly(3,3,4,4,5,5,6,6,7,7,8,8,8-tridecafluorooctylmethacrylate (PFOMA) and (poly(1H,1H,2H,2H-per fluorodecyl methacrylate) (PFDMA).

4. The template for metal electrode patterning according to claim 1,
wherein the substrate has a Normalized Resistance (R/R0) value of 70 or less within a uniaxial tensile strain of 0% to 100%.

5. The template for metal electrode patterning according to claim 1,
wherein the material that interferes with metal deposition is made of a material exhibiting a tensile stress of less than 0.4 MPa within a tensile strain of 0% to 800%.

6. A patterned metal electrode formed on a template,
comprising a first region in which a material that interferes with metal deposition is printed on the surface; and
a second region in which a metal electrode is deposited on the surface; and
comprising an elastic substrate comprising a polymer network structure inside,
wherein an intermediate layer in which metal atoms are impregnated into the network structure formed by polymers inside the substrate in the thickness direction from the surface where the electrode of the second region is formed.

7. The patterned metal electrode formed on a template according to claim 6,
wherein the metal electrode is formed of at least one metal selected from the group consisting of gold (Au), silver (Ag), magnesium (Mg), copper (Cu), iron (Fe) and calcium (Ca) or alloy thereof.

8. The patterned metal electrode formed on a template according to claim 6,
wherein the metal electrode comprises a pattern formed by physical vapor deposition (PVD).

9. The patterned metal electrode formed on a template according to claim 6,
wherein the metal electrode has a pattern formed without a mask only in the second region other than the first region in which a material that interferes with metal deposition is printed.

10. The patterned metal electrode formed on a template according to claim 6,
wherein in the intermediate layer, some metal atoms of the electrode are impregnated into the network structure formed by polymers inside the substrate at a ratio of 30 to 90%.

11. A light emitting device combined to a patterned metal electrode formed on a template,
comprising a first region in which a material that interferes with metal deposition is printed on the surface; and
a second region in which a metal electrode is deposited on the surface; and
comprising an elastic substrate comprising a polymer network structure inside,
wherein an intermediate layer in which metal atoms are impregnated into the polymer network structure inside the substrate in the thickness direction from the surface where the electrode of the second region is formed, and
the metal electrode is electrically connected to a light emitting device.

12. The light emitting device combined to a patterned metal electrode formed on a template according to claim 11,
wherein the elastic substrate is capable of being strained within a tensile strain range of 0 to 200%.

13. A manufacturing method of a patterned metal electrode formed on a template, which is a manufacturing method of a metal electrode, comprising;
preparing an preparing an elastic substrate;
forming a first region by printing a material that interferes with metal deposition on the substrate;
heat-treating the printed substrate; and
forming a metal electrode by exposing the heat-treated substrate to metal vapor in a high vacuum chamber,
wherein the manufacturing method of a metal electrode is performed using the template for metal electrode patterning of claim 1.
